(19) United States
(12) Patent Application Publication
(10) Pub. No.: US 2025/0019226 A1
(43) Pub. Date: Jan. 16, 2025

(54) MEMS DEVICE AND METHOD FOR PRODUCING MEMS DEVICE

(71) Applicant: ROHM CO., LTD., Kyoto (JP)

(72) Inventors: Toma FUJITA, Kyoto-shi (JP); Martin Wilfried HELLER, Kyoto-shi (JP)

(73) Assignee: ROHM CO., LTD., Kyoto (JP)

(21) Appl. No.: 18/770,989

(22) Filed: Jul. 12, 2024

(30) Foreign Application Priority Data
Jul. 14, 2023 (JP) 2023-116195

(51) Int. Cl. B81B 3/00; B81C 1/00; G01P 15/125

(52) U.S. Cl. CPC B81B 3/0056; B81C 1/00182; G01P 15/125; B81B 2201/0235; B81B 2203/0118; B81B 2203/0315; B81B 2203/04; B81C 2201/013; B81C 2201/0197

(57) ABSTRACT

A MEMS device includes a substrate and a MEMS electrode. The MEMS electrode includes a movable electrode finger relatively movable with respect to the substrate, a fixed electrode finger disposed at an interval from the movable electrode finger, and a beam portion cantilevered on the substrate and connecting the fixed electrode finger to the substrate. The beam portion includes a first portion having a first thermal expansion coefficient and a second portion disposed adjacent to the first portion and having a second thermal expansion coefficient different from the first thermal expansion coefficient. The beam portion is deformed due to a difference between thermal stress generated in the first portion and thermal stress generated in the second portion, and the interval is narrowed due to deformation of the beam portion as compared with an interval formed before the deformation of the beam portion.

### CROSS REFERENCE TO RELATED APPLICATION

This application claims benefit of priority to Japanese Patent Application 2023-116195, filed Jul. 14, 2023, the entire content of which is incorporated herein by reference.

### BACKGROUND

### Technical Field

The present disclosure relates to a MEMS device and a method for producing the MEMS device.

### Background Art

JP 2023-020325 A discloses an electrostatic capacitance type micro electro mechanical system (MEMS) sensor including a fixed electrode and a movable electrode that mesh in a comb shape and face each other. The fixed electrode and the movable electrode described in JP 2023-020325 A are formed by etching a semiconductor substrate.

### BRIEF DESCRIPTION OF DRAWINGS

FIG. 1 is a plan view of an acceleration sensor according to an embodiment of the present disclosure;

FIG. 2 is a sectional view taken along the line II-II in FIG. 1;

FIG. 3 is a flowchart for describing a step for producing the acceleration sensor according to the embodiment of the present disclosure;

FIG. 4 is a diagram for describing a step for producing the acceleration sensor according to the embodiment of the present disclosure;

FIG. 5 is a diagram for describing a step for producing the acceleration sensor according to the embodiment of the present disclosure;

FIG. 6 is a diagram for describing a step for producing the acceleration sensor according to the embodiment of the present disclosure;

FIG. 7 is a diagram for describing a step for producing the acceleration sensor according to the embodiment of the present disclosure;

FIG. 8 is a diagram for describing a step for producing the acceleration sensor according to the embodiment of the present disclosure;

FIG. 9 is a diagram for describing a step for producing the acceleration sensor according to the embodiment of the present disclosure;

FIG. 10 is a diagram for describing a step for producing the acceleration sensor according to the embodiment of the present disclosure; and

FIG. 11 is a sectional view similar to FIG. 2 according to a modification of the embodiment of the present disclosure.

### DETAILED DESCRIPTION

Hereinafter, a MEMS device and a method for producing the MEMS device according to an embodiment of the present disclosure will be described with reference to the accompanying drawings. The following description is merely exemplary in nature, and is not intended to limit the present disclosure, its application, or its use. The drawings are schematic, and ratios of dimensions and the like are different from actual ones.

### [Acceleration Sensor]

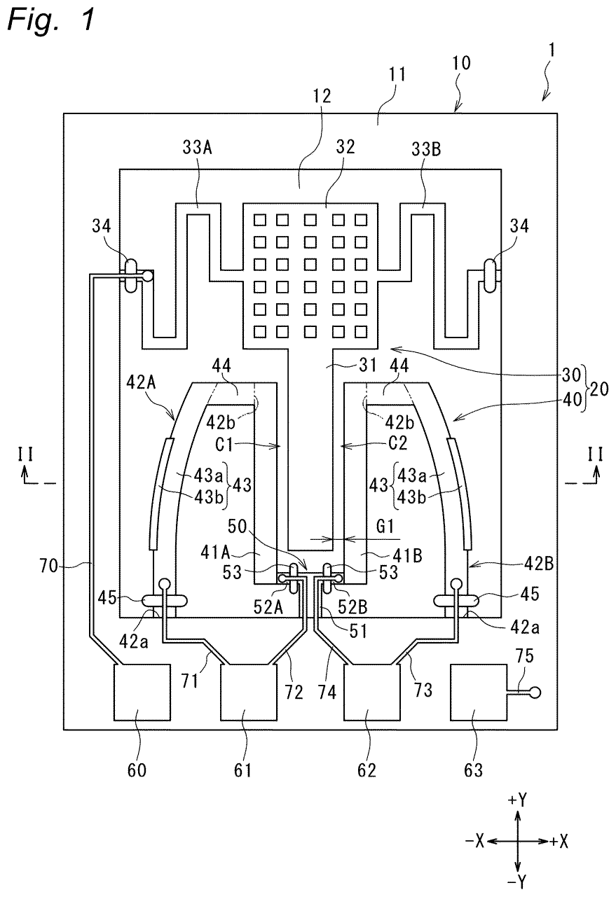

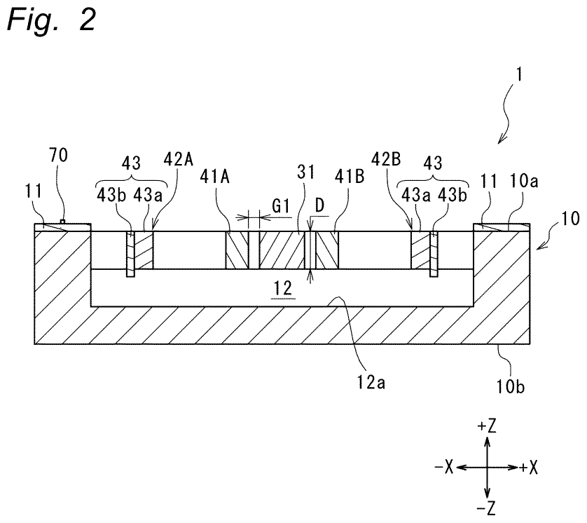

FIG. 1 is a plan view schematically illustrating an acceleration sensor 1 according to an embodiment of the present disclosure. FIG. 2 is a sectional view taken along the line II-II in FIG. 1. The acceleration sensor 1 according to the present embodiment is an electrostatic capacitance type acceleration sensor produced by using a semiconductor microfabrication technique. The acceleration sensor 1 of the present embodiment is an example of a micro electro mechanical system (MEMS) device according to the present disclosure.

In the following description, for convenience, among the directions along corresponding sides of the acceleration sensor 1 in the plan view illustrated in FIG. 1, a left-right direction in FIG. 1 is referred to as an X direction, an up-down direction in FIG. 1 is referred to as a Y direction, and a thickness direction (up-down direction in FIG. 2) of the acceleration sensor 1 in the sectional view illustrated in FIG. 2 is referred to as a Z direction. In particular, in FIG. 1, the right side may be referred to as a +X direction, the left side may be referred to as a −X direction, the upper side may be referred to as a +Y direction, and the lower side may be referred to as a −Y direction. In FIG. 2, the upper side may be referred to as a +Z direction, and the lower side may be referred to as a −Z direction. In the present embodiment, the X direction, the Y direction, and the Z direction are orthogonal to each other.

Referring to FIGS. 1 and 2, the acceleration sensor 1 includes a substrate 10 and a MEMS electrode 20 provided in the substrate 10.

The substrate 10 has a rectangular shape in plan view. The substrate 10 has a first main surface 10a located on the +Z side and a second main surface 10b located on the-Z side and opposite to the first main surface 10a. The substrate 10 is a conductive silicon (Si) substrate. The substrate 10 of the present embodiment includes only a single silicon layer. The first main surface 10a and the second main surface 10b extend in parallel to the X direction and the Y direction. An insulation layer 11 is disposed on the first main surface 10a of the substrate 10. In the substrate 10, a cavity 12 having a rectangular shape in plan view and recessed from the first main surface 10a toward the −Z side is formed.

The MEMS electrode 20 includes a movable electrode 30 and a fixed electrode 40. The movable electrode 30 and the fixed electrode 40 are disposed in the cavity 12.

The movable electrode 30 is separated from a bottom surface 12a of the cavity 12 toward the +Z side. The movable electrode 30 includes a movable electrode finger 31 extending in the Y direction, a base portion 32 to which a +Y side end portion of the movable electrode finger 31 is connected, and two spring portions 33A and 33B connecting the base portion 32 and the substrate 10. In the following description, when it is not necessary to particularly distinguish each of the spring portions 33A and 33B, one of the two spring portions 33A and 33B may be simply referred to as a spring portion 33.

The movable electrode finger 31 includes a conductive silicon (Si) layer. The movable electrode finger 31 is connected to the substrate 10 so as to be movable relative to the substrate 10 in the X direction.

The base portion 32 includes a conductive silicon (Si) layer. The base portion 32 functions as a proof mass of the acceleration sensor 1. The base portion 32 is connected to the substrate 10 so as to be movable relative to the substrate 10 in the X direction.

The spring portion 33 includes a conductive silicon (Si) layer. The spring portion 33 is cantilevered on a side surface of the substrate 10 extending in the Y direction and the Z direction. The spring portion 33 protrudes into the cavity 12 from the side surface of the substrate 10 extending in the Y direction and the Z direction. The spring portions 33A and 33B are disposed on the −X side and the +X side of the base portion 32, respectively. The spring portion 33 is configured to expand and contract in the X direction. When acceleration in the X direction acts on the base portion 32, the spring portions 33A and 33B are elastically deformed, which causes the movable electrode finger 31 to be displaced in the X direction.

The movable electrode 30 includes an isolation joint 34 that crosses the spring portion 33 in the Y direction and the Z direction and divides the spring portion in the X direction. The isolation joint 34 electrically insulates portions of the spring portion 33 on both sides divided in the X direction by the isolation joint 34 while mechanically connecting the portions. The isolation joint 34 electrically insulates the movable electrode finger 31 and the substrate 10 from each other. The isolation joint 34 of the present embodiment is made of silicon oxide (SiO₂).

The fixed electrode 40 is separated from the bottom surface 12a of the cavity 12 toward the +Z side. The fixed electrode 40 includes two fixed electrode fingers 41A and 41B extending in the Y direction, and two beam portions 42A and 42B respectively connecting the two fixed electrode fingers 41A and 41B to the substrate 10. In the following description, when it is not necessary to particularly distinguish each of the two fixed electrode fingers 41A and 41B, one of the two fixed electrode fingers 41A and 41B may be simply referred to as a fixed electrode finger 41. In the same manner, in the following description, when it is not necessary to particularly distinguish each of the two beam portions 42A and 42B, one of the two beam portions 42A and 42B may be simply referred to as a beam portion 42.

The fixed electrode finger 41 includes a conductive silicon (Si) layer. The two fixed electrode fingers 41A and 41B extend in the Y direction and are disposed side by side in the X direction. The two fixed electrode fingers 41A and 41B are disposed with the movable electrode finger 31 interposed therebetween in the X direction. The fixed electrode finger 41 faces the movable electrode finger 31 in the X direction. The fixed electrode finger 41 is disposed at an interval G1 from the movable electrode finger 31 in the X direction. In the present embodiment, the aspect ratio of the space between the movable electrode finger 31 and the fixed electrode finger 41, that is, the ratio D/G1 of a depth D, that is, the dimension in the Z direction of the movable electrode finger 31 and the fixed electrode finger 41 with respect to the interval G1 between the movable electrode finger 31 and the fixed electrode finger 41 in the X direction is, for example, 100 or more.

The beam portion 42 is cantilevered by the substrate 10. The beam portion 42 protrudes and extends into the cavity 12 from a side surface of the substrate 10 extending in the X direction and the Z direction. The beam portion 42 includes a first end portion 42a coupled to the substrate 10 and a second end portion 42b coupled to the +Y side end portion of the fixed electrode finger 41. The beam portion 42 includes a first beam 43 curved toward the movable electrode finger 31 in the X direction from the first end portion 42a toward the +Y side in plan view, and a second beam 44 extending from the +Y side end portion of the first beam 43 toward the movable electrode finger 31 in the X direction. That is, the beam portion 42 of the present embodiment has a substantially L-shape in plan view.

The first beam 43 is disposed side by side with the fixed electrode finger 41 in the X direction. Specifically, in the beam portion 42A, the first beam 43 is disposed on the −X side of the fixed electrode finger 41A, and in the beam portion 42B, the first beam 43 is disposed on the +X side of the fixed electrode finger 41B. The first beam 43 of the present embodiment is curved toward the fixed electrode finger 41 side in the X direction from the first end portion 42a toward the +Y side. Specifically, the first beam 43 of the beam portion 42A of the present embodiment is curved toward the fixed electrode finger 41A side, that is, the +X side from the first end portion 42a toward +Y side, and the first beam 43 of the beam portion 42B is curved toward the fixed electrode finger 41B side, that is, the −X side from the first end portion 42a toward the +Y side.

The first beam 43 includes a first portion 43a having a first thermal expansion coefficient and a second portion 43b disposed adjacent to the first portion 43a in the X direction and having a second thermal expansion coefficient different from the first thermal expansion coefficient. Here, the first thermal expansion coefficient and the second thermal expansion coefficient are linear thermal expansion coefficients in the Y direction. In the present embodiment, the first thermal expansion coefficient is larger than the second thermal expansion coefficient.

The first portion 43a includes a conductive silicon (Si) layer. The first portion 43a extends in a curved manner toward the movable electrode finger 31 in the X direction toward the +Y side.

The second portion 43b of the present embodiment is made of silicon oxide (SiO₂) formed by thermally oxidizing the substrate 10. The second thermal expansion coefficient of the second portion 43b is smaller than the first thermal expansion coefficient of the first portion 43a. The second portion 43b extends in a curved manner toward the movable electrode finger 31 in the X direction toward the +Y side. That is, the second portion 43b extends along the first portion 43a. The second portion 43b is disposed on the side opposite to the fixed electrode finger 41 with respect to the first portion 43a in the X direction. In the beam portion 42A, the second portion 43b is disposed adjacent to −X side of the first portion 43a. In the beam portion 42B, the second portion 43b is disposed adjacent to +X side of the first portion 43a.

The second beam 44 includes a conductive silicon (Si) layer. The second beam 44 extends in the X direction so as to connect the +Y side end portion of the first beam 43 and the +Y side end portion of the fixed electrode finger 41.

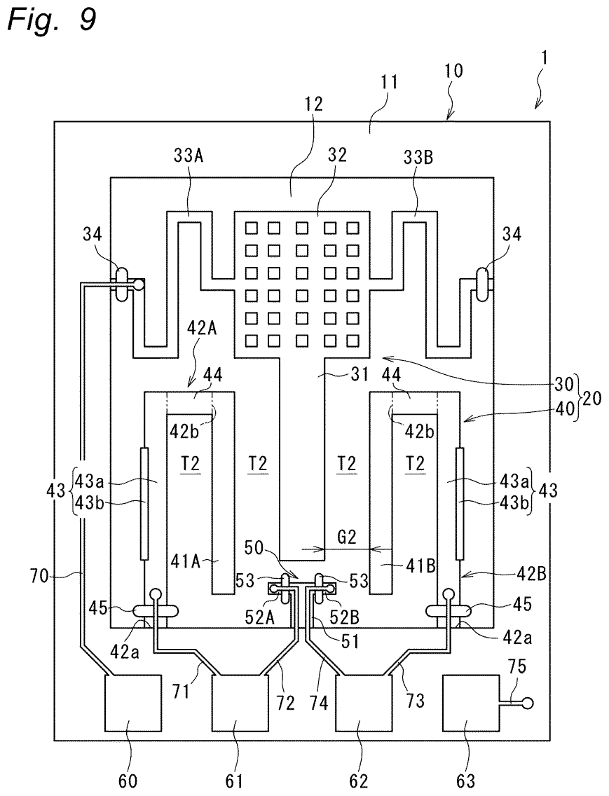

The beam portion 42 is deformed by a difference in thermal stress generated in the first portion 43a and the second portion 43b in the step of forming the second portion 43b in the method of producing the acceleration sensor 1. Specifically, the first beam 43 linearly extending in the Y direction in the beam portion 42 before deformation is deformed so as to be curved toward the movable electrode finger 31 side in the X direction toward the +Y side due to a difference in thermal stress generated in the first portion 43a and the second portion 43b. As a result, the interval G1 between the movable electrode finger 31 and the fixed electrode finger 41 in the X direction is narrower than the interval G2 before deformation (illustrated in FIG. 9).

The beam portion 42 includes an isolation joint 45 that crosses the first beam 43 in the X direction and the Z direction and divides the first beam 43 in the Y direction. The isolation joint 45 electrically insulates portions of the beam portion 42 on both sides divided in the Y direction by the isolation joint 45 while mechanically connecting the portions. The isolation joint 45 electrically insulates the fixed electrode finger 41 and the substrate 10 from each other. The isolation joint 45 of the present embodiment is made of silicon oxide (SiO₂).

The acceleration sensor 1 includes a restriction portion 50 connected to the substrate 10. When the beam portion 42 of the fixed electrode 40 is deformed by thermal stress and the fixed electrode finger 41 is displaced toward the movable electrode finger 31 by a predetermined distance or more, the restriction portion 50 comes into contact with the fixed electrode finger 41 to restrict the displacement of the fixed electrode finger 41. Accordingly, the restriction portion 50 maintains the interval G between the movable electrode finger 31 and the fixed electrode finger 41 at a predetermined interval G1.

The restriction portion 50 includes a body 51 extending in the Y direction and two protrusions 52A and 52B protruding from the body 51 to each side in the X direction, respectively. When it is not necessary to particularly distinguish each of the two protrusions 52A and 52B, one of the two protrusions 52A and 52B may be simply referred to as a protrusion 52.

The body 51 includes a conductive silicon (Si) layer. The body 51 protrudes into the cavity 12 from the side surface of the substrate 10 extending in the X direction and the Z direction.

The protrusion 52 includes a conductive silicon (Si) layer. The protrusion 52A protrudes to the −X side from the +Y side end portion of the body 51, and the protrusion 52B protrudes to the +X side from the +Y side end portion of the body 51.

The restriction portion 50 includes an isolation joint 53 that crosses the protrusion 52 in the Y direction and the Z direction and divides the protrusion in the X direction. The isolation joint 53 electrically insulates portions of the protrusion 52 on both sides divided in the X direction by the isolation joint 53 while mechanically connecting the portions. The isolation joint 53 electrically insulates the portion of the protrusion 52 facing the fixed electrode finger 41 from the substrate 10. The isolation joint 53 of the present embodiment is made of silicon oxide (SiO₂).

The acceleration sensor 1 includes electrode pads 60 to 63 to which an electric signal (voltage) is input and output with respect to the MEMS electrode 20. Different voltages are applied to the electrode pads 60 to 63. The electrode pads 60 to 63 are disposed on the insulation layer 11.

The electrode pad 60 is electrically connected to the movable electrode 30 via a wiring layer 70. The wiring layer 70 is electrically insulated from the substrate 10 by the insulation layer 11.

The electrode pad 61 is electrically connected to the fixed electrode finger 41A via a wiring layer 71, and is electrically connected to the portion of the protrusion 52A of the restriction portion 50 facing the fixed electrode finger 41A via a wiring layer 72. Thus, the fixed electrode finger 41A and the portion of the protrusion 52A in contact with the fixed electrode finger 41A are connected at the same potential. The wiring layers 71 and 72 are electrically insulated from the substrate 10 by the insulation layer 11.

The electrode pad 62 is electrically connected to the fixed electrode finger 41B via a wiring layer 73, and is electrically connected to the portion of the protrusion 52B of the restriction portion 50 facing the fixed electrode finger 41B via a wiring layer 74. Thus, the fixed electrode finger 41B and the portion of the protrusion 52B in contact with the fixed electrode finger 41B are connected at the same potential. The wiring layers 73 and 74 are electrically insulated from the substrate 10 by the insulation layer 11.

The electrode pad 63 is electrically connected to the substrate 10 via a wiring layer 75.

In the acceleration sensor 1 of the present embodiment, the movable electrode finger 31 and the fixed electrode finger 41A disposed adjacent to the movable electrode finger 31 on the −X side constitute a first capacitor C1. The movable electrode finger 31 and the fixed electrode finger 41B disposed adjacent to the movable electrode finger 31 on the +X side constitute a second capacitor C2.

When acceleration in the X direction acts on the acceleration sensor 1, the movable electrode finger 31 moves relative to the fixed electrode 40 in the X direction. The acceleration sensor 1 is configured to detect acceleration by detecting a change in electrostatic capacitance in each of the first capacitor C1 and the second capacitor C2 due to displacement of the movable electrode 30 in the X direction when acceleration acts.

### [Method for Producing Acceleration Sensor]

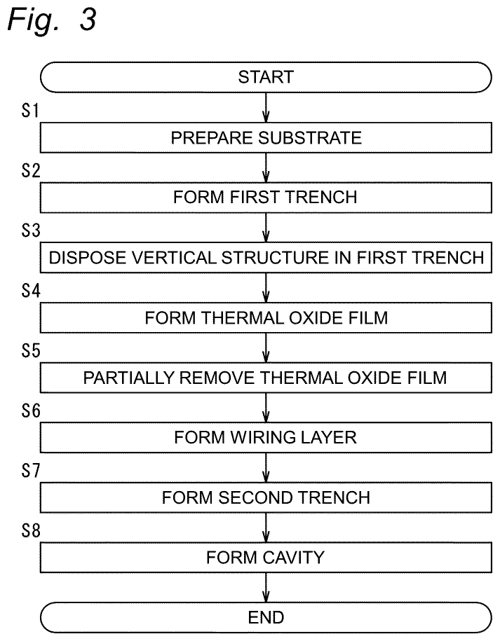

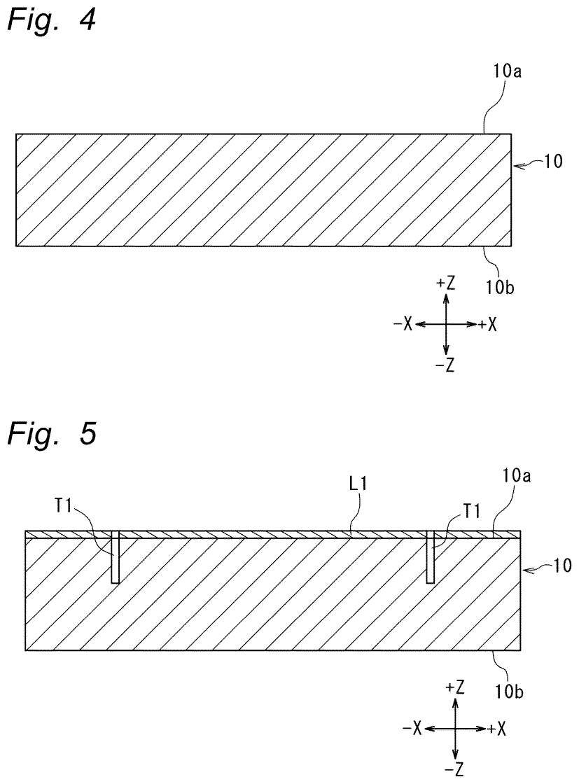

A method for producing the acceleration sensor 1, in particular, a method for producing a structure around the fixed electrode 40 will be described with reference to FIGS. 3 to 10. FIG. 3 is a flowchart for describing a method for producing the acceleration sensor 1 according to the present embodiment. FIGS. 4 to 10 are diagrams for describing the method for describing the acceleration sensor 1 of the present embodiment. FIGS. 4 to 8 and 10 illustrate sectional views similar to FIG. 2, and FIG. 9 illustrates a plan view similar to FIG. 1.

In step S1, as illustrated in FIG. 4, the substrate 10 including a silicon (Si) layer is prepared. The substrate 10 of the present embodiment includes only a single silicon layer. The substrate 10 has the first main surface 10a located on the +Z side and the second main surface 10b located on the Z side and opposite to the first main surface 10a.

Next, in step S2, as illustrated in FIG. 5, a first trench T1 extending from the first main surface 10a of the substrate 10 toward the second main surface 10b is formed. Specifically, a first silicon oxide (SiO₂) layer L1 in which a part of the first main surface 10a is exposed is formed on the first main surface 10a of the substrate 10 in order to form the second portion 43b (illustrated in FIG. 1). Next, using the first silicon oxide layer L1 as a hard mask, the first trench T1 is formed by digging the substrate 10 from the first main surface 10a to the −Z side through anisotropic etching. In the present embodiment, the first trench T1 extends linearly in the Y direction in plan view. Although not illustrated, trenches for forming the isolation joints 34, 45, and 53 may be formed in the substrate 10 in step S2.

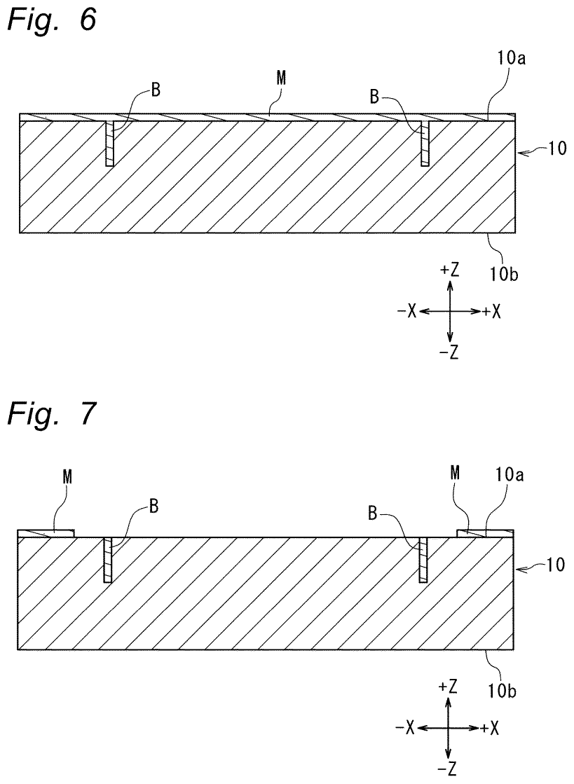

Next, in step S3, as illustrated in FIG. 6, a vertical structure B having a second thermal expansion coefficient different from the first thermal expansion coefficient of the substrate 10 is formed in the first trench T1. In the present embodiment, the vertical structure B is formed by thermally oxidizing the wall surface of the first trench T1. Specifically, after the first silicon oxide layer L1 (illustrated in FIG. 5) is removed from the substrate 10, the substrate 10 is thermally oxidized from the +Z side to form a thermal oxide film which is thermal oxide silicon on the inner wall surface of the first trench T1. The thermal oxide film formed on the inner wall surface of the first trench T1 fills the inside of the first trench Tl to form the vertical structure B. That is, in the present embodiment, the vertical structure B is a structure made of silicon oxide (SiO₂) obtained by thermally oxidizing the substrate 10. In the present embodiment, the vertical structure B extends linearly in the Y direction in plan view. The second portion 43b of the beam portion 42 is formed of the vertical structure B. Although not illustrated, in step S3, the isolation joints 34, 45, and 53 may be formed in the same mechanism as the formation of the vertical structure B by thermally oxidizing the wall surfaces of the trenches for forming the isolation joints 34, 45, and 53 formed in step S2.

In the present embodiment, the vertical structure B has the second thermal expansion coefficient lower than the first thermal expansion coefficient of the substrate 10. The thermal oxidation of the first trench T1 is performed at a high temperature (for example, 800 to 1200° C.). When the vertical structure B formed at a high temperature is cooled, shrinkage of the vertical structure B due to cooling is restricted by a portion of the substrate 10 disposed around the vertical structure B, and thus strain remains and thermal stress is generated inside the vertical structure B. In the same manner, strain remains and thermal stress is generated in a portion of the substrate 10 disposed around the vertical structure B

In step S4, as illustrated in FIG. 6, a thermal oxide film M is formed on the first main surface 10a of the substrate 10. In the present embodiment, the formation of the thermal oxide film M in step S4 is performed in the same step as the formation of the vertical structure B in the first trench T1 in step S3. Specifically, after the first silicon oxide layer L1 (illustrated in FIG. 5) is removed from the substrate 10, the substrate 10 is thermally oxidized from the +Z side to form the thermal oxide film M, which is thermal silicon oxide, on the first main surface 10a. The thermal oxide film M formed on the first main surface 10a constitutes an insulation layer 11 (illustrated in FIG. 1).

Next, in step S5, as illustrated in FIG. 7, a portion corresponding to the cavity 12 (illustrated in FIG. 1) in the thermal oxide film M formed on the first main surface 10a of the substrate 10 is partially removed.

Next, in step S6, although not illustrated, the wiring layers 70 to 75 (illustrated in FIG. 1) are formed in a predetermined pattern.

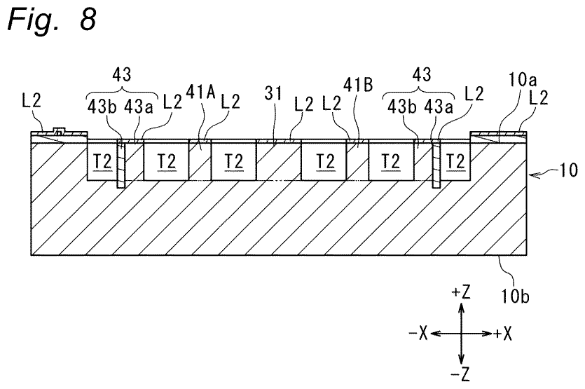

Next, in step S7, as illustrated in FIGS. 8 and 9, a second trench T2 extending from the first main surface 10a of the substrate 10 toward the second main surface 10b is formed. Specifically, the second silicon oxide layer L2 is formed at a portion corresponding to the MEMS electrode 20 on the +X side of the first main surface 10a of the substrate 10. Next, using the second silicon oxide layer L2 as a hard mask, the second trench T2 is formed by digging the substrate 10 from the first main surface 10a to the −Z side through anisotropic etching. As illustrated in FIG. 9, the MEMS electrode 20 is partitioned in the substrate 10 by the second trench T2. Specifically, the second trench T2 partition the movable electrode finger 31, the fixed electrode finger 41, and the beam portion 42 on the substrate 10.

In the state where the MEMS electrode 20 is partitioned in the substrate 10, the first beam 43 linearly extends in the Y direction as illustrated in FIG. 9. In the state illustrated in FIGS. 8 and 9, the interval G2 in the X direction between the movable electrode finger 31 and the fixed electrode finger 41 is larger than the interval G1 in the X direction between the movable electrode finger 31 and the fixed electrode finger 41 in the state illustrated in FIG. 1. In the state illustrated in FIGS. 8 and 9, the movement of the fixed electrode finger 41 and the beam portion 42, which are partitioned, is restrained by a portion of the substrate 10 located on the −Z side of the fixed electrode finger 41 and the beam portion 42.

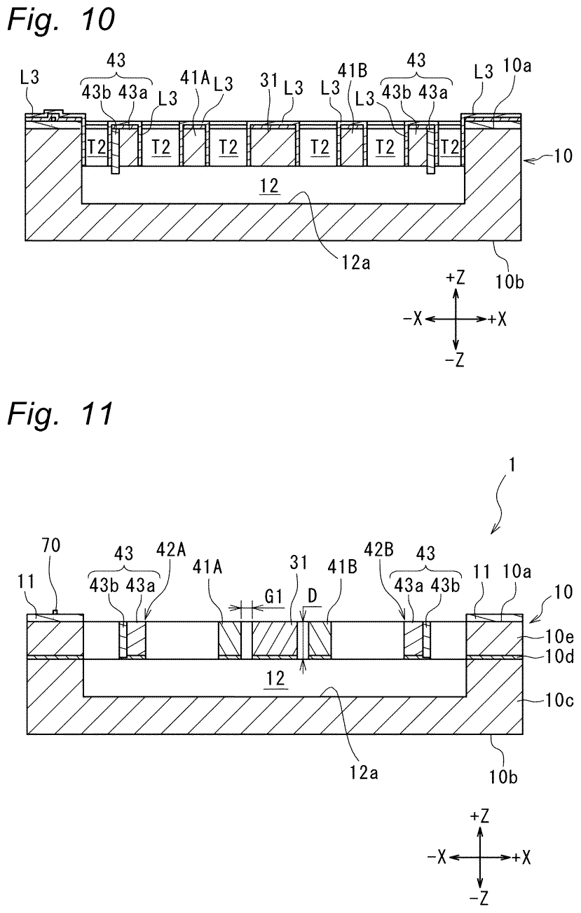

Next, in step S8, the cavity 12 is formed. Specifically, as illustrated in FIG. 10, a third silicon oxide layer L3 is formed on the inner wall surface of the second trench T2, and the third silicon oxide layer L3 is removed at a bottom of the second trench T2. Thereafter, the bottom portion of the second trench T2 is removed through isotropic etching, whereby the portion of the substrate 10 located on the −Z side of the MEMS electrode 20 is removed. As a result, by connecting the bottoms of the adjacent second trenches T2 to each other, the cavity 12 is formed, and the MEMS electrode 20 is formed so as to be separated (also referred to as released) from the bottom surface 12a of the cavity 12 toward the +Z side.

Finally, although not illustrated, the second silicon oxide layer L2 and the third silicon oxide layer L3 are removed, whereby the acceleration sensor 1 is formed.

After the MEMS electrode 20 is separated from the bottom surface 12a of the cavity 12, the first beam 43 deforms to be curved due to a difference between thermal stress generated in the first portion 43a and thermal stress generated in the second portion 43b (vertical structure B), as described in detail below.

When the MEMS electrode 20 is released from the bottom surface 12a of the cavity 12, thermal stress for compressing the first portion 43a in the Y direction is generated in the first portion 43a linearly extending in the Y direction in plan view. In the same manner, when the MEMS electrode 20 is released from the bottom surface 12a of the cavity 12, thermal stress for compressing the second portion 43b in the Y direction is also generated in the second portion 43b linearly extending in the Y direction in plan view. Here, since the first thermal expansion coefficient of the first portion 43a is larger than the second thermal expansion coefficient of the second portion 43b, the thermal stress for compressing the first portion 43a in the Y direction is larger than the thermal stress for compressing the second portion 43b in the Y direction. Thus, the amount of shrinkage in the Y direction of the first portion 43a of the first beam 43 disposed on the fixed electrode finger 41 side in the X direction is larger than the amount of shrinkage in the Y direction of the second portion 43b of the first beam 43 disposed on the side opposite to the fixed electrode finger 41 with respect to the first portion 43a in the X direction, whereby the first beam 43 curves toward the +Y side toward the fixed electrode finger 41.

Due to the deformation of the first beam 43, the fixed electrode finger 41 is displaced so as to move towards the movable electrode finger 31. As a result, the interval between the movable electrode finger 31 and the fixed electrode finger 41 is narrower than the interval G2 when etching is performed to partition the movable electrode finger 31 and the fixed electrode finger 41. In the present embodiment, when the fixed electrode finger 41 is displaced by a predetermined distance or more due to the deformation of the beam portion 42, the fixed electrode finger 41 comes into contact with the protrusion 52 of the restriction portion 50 to restrict the displacement. This keeps the interval G1 between the movable electrode finger 31 and the fixed electrode finger 41 at a predetermined interval.

### [Effects]

When etching is performed between the movable electrode finger 31 and the fixed electrode finger 41, there is a limit to the aspect ratio of the etching, and thus, the interval between the movable electrode finger 31 and the fixed electrode finger 41 is widened according to the depth of the etching. In other words, when the space between the movable electrode finger 31 and the fixed electrode finger 41 is etched at a predetermined depth, it is difficult to make the interval between the fixed electrode finger 41 and the movable electrode finger 31 narrower than a certain interval. On the other hand, according to this configuration, the beam portion 42 is deformed by the difference between the thermal stress generated in the first portion 43a and the thermal stress generated in the second portion 43b, and this deformation of the beam portion 42 makes it possible to make the interval between the movable electrode finger 31 and the fixed electrode finger 41 narrower than the interval G2 formed before the beam portion 42 is deformed. Thus, for example, the interval G1 between the movable electrode finger 31 and the fixed electrode finger 41 can be made narrower than the interval G2 formed when the fixed electrode finger 41 and the beam portion 42 are separated from the bottom surface 12a of the cavity 12. That is, the interval G1 between the movable electrode finger 31 and the fixed electrode finger 41 can be made narrower than the interval G2 formed between the fixed electrode finger 41 and the movable electrode finger 31 by etching for forming the fixed electrode finger 41 and the movable electrode finger 31.

As a result, regardless of the limit of the aspect ratio of etching, the interval between the fixed electrode finger 41 and the movable electrode finger 31 can be narrowed, and thus the sensitivity can be improved in the MEMS device.

According to the acceleration sensor 1 of the present embodiment, since the displacement of the fixed electrode finger 41 in the X direction is restricted by the restriction portion 50, the interval G1 between the movable electrode finger 31 and the fixed electrode finger 41 can be kept at a predetermined interval regardless of a production error or a temperature change.

According to the acceleration sensor 1 of the embodiment, the portion of the restriction portion 50 in contact with the fixed electrode finger 41 is connected at the same potential as that of the fixed electrode finger 41. Thus, when the fixed electrode finger 41 is in contact with the restriction portion 50, no current flows from the fixed electrode finger 41 to the restriction portion 50. As a result, a decrease in sensitivity of the MEMS device can be suppressed.

The MEMS device according to the present disclosure is not limited to the configuration of the above embodiment, and various modifications can be made.

In the above embodiment, the acceleration sensor 1 has been described as an example of the MEMS device, but the present disclosure can be applied to various MEMS devices having a MEMS electrode. For example, the MEMS device according to the present disclosure may be a MEMS oscillator or an acceleration sensor.

In the above embodiment, the acceleration sensor 1 includes the restriction portion 50, but the present disclosure is not limited to this configuration. That is, the acceleration sensor 1 does not have to include the restriction portion 50.

In the above embodiment, the fixed electrode finger 41 and the portion of the restriction portion 50 in contact with the fixed electrode finger 41 are electrically connected at the same potential, but the present disclosure is not limited to this configuration. That is, the fixed electrode finger 41 and the portion of the restriction portion 50 in contact with the fixed electrode finger 41 may be electrically connected at different potentials.

The shape and structure of the beam portion 42 are not limited to those exemplified in the above embodiment. The shape and structure of the beam portion 42 can be changed as long as the beam portion 42 has a function of being deformed by thermal stress so that the interval G1 between the movable electrode finger 31 and the fixed electrode finger 41 after deformation becomes narrower than the interval G2 between the movable electrode finger 31 and the fixed electrode finger 41 before deformation.

The positions, sizes, ranges, materials, and the like of the first portion 43a and the second portion 43b are not limited to those exemplified in the above embodiment. The positions, sizes, ranges, materials, and the like of the first portion 43a and the second portion 43b can be changed as long as the beam portion 42 has a function of being deformed by thermal stress so that the interval G1 between the movable electrode finger 31 and the fixed electrode finger 41 after deformation becomes narrower than the interval G2 between the movable electrode finger 31 and the fixed electrode finger 41 before deformation. For example, in the above embodiment, the first portion 43a is formed of silicon (Si), and the second portion 43b is formed of silicon oxide (SiO₂), but the present disclosure is not limited to this configuration. The first portion 43a may be formed of a material different from that of the substrate 10.

In the above embodiment, a case where the substrate 10 includes only a single silicon layer has been described, but the substrate according to the present disclosure may include another layer such as a silicon oxide (SiO₂) layer or silicon carbide (SiC) in addition to the silicon layer. For example, the substrate according to the present disclosure may be a silicon on insulator (SOI) substrate. Specifically, as in the modification illustrated in FIG. 11, the substrate 10 may include a support layer 10c made of silicon, an insulation layer 10d made of silicon oxide and stacked on the +Z side of the support layer 10c, and an active layer 10e made of silicon and stacked on the +Z side of the insulation layer 10d.

### [Supplementary Note]

The MEMS device and the method for producing the MEMS device according to the present disclosure provide the following aspects.

### [Aspect 1]

Provided is a MEMS device including:

a substrate having a first main surface and a second main surface opposite to the first main surface, wherein a cavity recessed from the first main surface side toward the second main surface side is disposed; and

a MEMS electrode disposed in the cavity and spaced apart toward the first main surface with respect to a bottom surface of the cavity,

wherein

the MEMS electrode includes:
a movable electrode finger connected to the substrate, the movable electrode finger being relatively movable with respect to the substrate;
a fixed electrode finger disposed at an interval from the movable electrode finger, the fixed electrode finger facing the movable electrode finger; and
a beam portion that is cantilevered on the substrate and connects the fixed electrode finger to the substrate,

the beam portion includes:
a first portion having a first thermal expansion coefficient; and
a second portion disposed adjacent to the first portion, the second portion having a second thermal expansion coefficient different from the first thermal expansion coefficient, and

the beam portion is deformed due to a difference between thermal stress generated in the first portion and thermal stress generated in the second portion, and an interval between the fixed electrode finger and the movable electrode finger is narrowed due to deformation of the beam portion as compared with an interval formed before the deformation of the beam portion.

When etching is performed between the movable electrode finger and the fixed electrode finger, there is a limit to the aspect ratio of the etching, and thus, the interval between the movable electrode finger and the fixed electrode finger is widened according to the depth of the etching. In other words, when the space between the movable electrode finger and the fixed electrode finger is etched at a predetermined depth, it is difficult to make the interval between the fixed electrode finger and the movable electrode finger narrower than a certain interval. On the other hand, according the MEMS device according to Aspect 1, the beam portion is deformed by the difference between the thermal stress generated in the first portion and the thermal stress generated in the second portion, and this deformation of the beam portion makes it possible to make the interval between the movable electrode finger and the fixed electrode finger narrower than the interval before the beam portion is deformed. Thus, for example, the interval between the movable electrode finger and the fixed electrode finger can be made narrower than the interval formed when the fixed electrode finger and the beam portion are separated from the bottom surface of the cavity. That is, the interval between the movable electrode finger and the fixed electrode finger can be made narrower than the interval formed between the fixed electrode finger and the movable electrode finger by etching for forming the fixed electrode finger and the movable electrode finger. As a result, regardless of the limit of the aspect ratio of etching, the interval between the fixed electrode finger and the movable electrode finger can be narrowed, and thus the sensitivity can be improved in the MEMS device.

### [Aspect 2]

Provided is the MEMS device according to Aspect 1, wherein the substrate includes a restriction portion that restricts displacement of the fixed electrode finger by coming into contact with the fixed electrode finger when the fixed electrode finger is displaced toward the movable electrode finger by a predetermined distance or more due to the deformation of the beam portion.

### [Aspect 3]

Provided is the MEMS device according to Aspect 2, wherein a portion of the restriction portion, the portion being in contact with the fixed electrode finger, is connected at a same potential as the fixed electrode finger.

[Aspect 4]

Provided is a method for producing a MEMS device, the method including:

preparing a substrate having a first main surface and a second main surface opposite to the first main surface;

forming a first trench extending from the first main surface toward the second main surface of the substrate;

forming a vertical structure having a thermal expansion coefficient different from a thermal expansion coefficient of the substrate in the first trench by thermally oxidizing a wall surface of the first trench;

forming a second trench extending from the first main surface toward the second main surface of the substrate through anisotropic etching to partition a movable electrode finger, a fixed electrode finger, and a beam portion in the substrate with the second trench, wherein the vertical structure is included in the beam portion; and

forming a cavity by at least partially removing a portion of the substrate, which portion is located on the second main surface side of the movable electrode finger, the fixed electrode finger, and the beam portion that have been partitioned, and forming the fixed electrode finger, the movable electrode finger, and the beam portion separated from a bottom surface of the cavity,

wherein

after the beam portion is separated from the bottom surface of the cavity, the beam portion deforms due to thermal stress generated in the beam portion due to a difference between thermal stress generated in a portion of the beam portion, the portion being adjacent to the vertical structure and thermal stress generated in the vertical structure, and an interval between the fixed electrode finger and the movable electrode finger becomes narrower due to deformation of the beam portion as compared with the interval formed before deformation of the beam portion.

### EXPLANATION OF REFERENCES

1 acceleration sensor (MEMS device)
10 substrate
10a first main surface
10b second main surface
11 insulation layer
12 cavity
12a bottom surface
20 MEMS electrode
30 movable electrode
31 movable electrode finger
32 base portion
33 spring portion
34 isolation joint
40 fixed electrode
41 fixed electrode finger
42 beam portion
42a first end portion
42b second end portion
43 first beam
43a first portion
43b second portion
44 second beam
45 isolation joint
50 restriction portion
51 body
52 protrusion
53 isolation joint
60 electrode pad
61 electrode pad
62 electrode pad
63 electrode pad
70 wiring layer
71 wiring layer
72 wiring layer
73 wiring layer
74 wiring layer
75 wiring layer

What is claimed is:

1. A MEMS device comprising:
a substrate having a first main surface and a second main surface opposite to the first main surface, wherein a cavity recessed from the first main surface side toward the second main surface side is disposed; and
a MEMS electrode disposed in the cavity and spaced apart toward the first main surface with respect to a bottom surface of the cavity, wherein
the MEMS electrode includes:
a movable electrode finger connected to the substrate, the movable electrode finger being relatively movable with respect to the substrate;
a fixed electrode finger disposed at an interval from the movable electrode finger, the fixed electrode finger facing the movable electrode finger; and
a beam portion that is cantilevered on the substrate and connects the fixed electrode finger to the substrate,
the beam portion includes:
a first portion having a first thermal expansion coefficient; and
a second portion disposed adjacent to the first portion, the second portion having a second thermal expansion coefficient different from the first thermal expansion coefficient, and
the beam portion is deformed due to a difference between thermal stress generated in the first portion and thermal stress generated in the second portion, and an interval between the fixed electrode finger and the movable electrode finger is narrowed due to deformation of the beam portion as compared with an interval formed before the deformation of the beam portion.

2. The MEMS device according to claim 1, wherein the substrate includes a restriction portion that restricts displacement of the fixed electrode finger by coming into contact with the fixed electrode finger when the fixed electrode finger is displaced toward the movable electrode finger by a predetermined distance or more due to the deformation of the beam portion.

3. The MEMS device according to claim 2, wherein a portion of the restriction portion, the portion being in contact with the fixed electrode finger, is connected at a same potential as the fixed electrode finger.

4. A method for producing a MEMS device, the method comprising:
preparing a substrate having a first main surface and a second main surface opposite to the first main surface;
forming a first trench extending from the first main surface toward the second main surface of the substrate;
forming a vertical structure having a thermal expansion coefficient different from a thermal expansion coefficient of the substrate in the first trench by thermally oxidizing a wall surface of the first trench;
forming a second trench extending from the first main surface toward the second main surface of the substrate through anisotropic etching to partition a movable electrode finger, a fixed electrode finger, and a beam portion in the substrate with the second trench, wherein the vertical structure is included in the beam portion; and
forming a cavity by at least partially removing a portion of the substrate, which located on the second main surface side of the movable electrode finger, the fixed electrode finger, and the beam portion that have been partitioned, and forming the fixed electrode finger, the movable electrode finger, and the beam portion separated from a bottom surface of the cavity,
wherein after the beam portion is separated from the bottom surface of the cavity, the beam portion deforms due to thermal stress generated in the beam portion due to a difference between thermal stress generated in a portion of the beam portion, the portion being adjacent to the vertical structure and thermal stress generated in the vertical structure, and an interval between the fixed electrode finger and the movable electrode finger becomes narrower due to deformation of the beam portion as compared with the interval formed before deformation of the beam portion.
